(19) United States
(12) Patent Application Publication
(10) Pub. No.: US 2013/0135934 A1
(43) Pub. Date: May 30, 2013

(54) NONVOLATILE MEMORY DEVICE AND OPERATING METHOD THEREOF

(71) Applicants: Seung-Bum KIM, Hwaseong-si (KR); Jaeyong JEONG, Yongin-si (KR); Kitae PARK, Seongnam-do (KR)

(72) Inventors: Seung-Bum KIM, Hwaseong-si (KR); Jaeyong JEONG, Yongin-si (KR); Kitae PARK, Seongnam-do (KR)

(73) Assignee: SAMSUNG ELECTRONICS CO., LTD., Suwon-si (KR)

(21) Appl. No.: 13/599,773

(22) Filed: Aug. 30, 2012

(30) Foreign Application Priority Data
Nov. 30, 2011 (KR) 10-2011-0127049

(51) Int. Cl. G11C 16/04

(52) U.S. Cl. 365/185.18

(57) ABSTRACT

Disclosed is a method of operating a nonvolatile memory device which includes a first memory area and a second memory area, the number of pages being stored in each word line of the first memory area being smaller than the number of pages being stored in each word line of the second memory area, and the first memory area being configured to buffer data to be written in the second memory area. The method includes sensing pages stored in the first memory area to store the sensed pages in a page buffer; receiving an address for storing pages stored in the page buffer in the second memory area; and randomizing the pages stored in the page buffer based on the address.

### CROSS-REFERENCE TO RELATED APPLICATIONS

A claim for priority under 35 U.S.C §119 is made to Korean Patent Application No. 10-2011-0127049 filed on Nov. 30, 2011 in the Korean Intellectual Property Office (KIPO), the entirety of which is incorporated by reference herein.

### BACKGROUND

The example embodiments described herein relate to a semiconductor memory device, and more particularly, to a nonvolatile memory device and an operating method thereof.

Semiconductor memory devices may be roughly classified into volatile semiconductor memory devices and nonvolatile semiconductor memory devices. The volatile semiconductor memory devices can perform read and write operations in a high speed, while contents stored therein may be lost at power-off. The nonvolatile semiconductor memory devices may retain contents stored therein even at power-off. The nonvolatile semiconductor memory devices may be used to store contents which must be retained regardless of whether they are powered.

The nonvolatile semiconductor memory devices may include a Mask Read-Only Memory (MROM), a Programmable ROM (PROM), an Erasable Programmable ROM (EPROM), an Electrically Erasable Programmable ROM (EEPROM), and the like.

A representative nonvolatile memory device may be a flash memory device. The flash memory device may be widely used as a voice and image data storing medium of information appliances such as a computer, a cellular phone, a PDA, a digital camera, a camcorder, a voice recorder, an MP3 player, a handheld PC, a game machine, a facsimile, a scanner, a printer, and the like, which are referred to as a host).

Recently, a multi-bit memory device storing multi-bit data in one memory cell may be becoming increasingly common according to an increasing need for the integrity. It is desirable to manage a threshold voltage distribution of memory cells in order to improve the reliability of multi-level cells.

### SUMMARY

According to at least one example embodiment, a method of operating a nonvolatile memory device is provided which includes a first memory area and a second memory area, the number of pages being stored in each word line of the first memory area being smaller than the number of pages being stored in each word line of the second memory area, and the first memory area being configured to buffer data to be written in the second memory area, the method comprising reading pages stored in the first memory area; storing the pages read from the first memory area in a page buffer; receiving an address; and randomizing data of the pages stored in the page buffer based on the address.

According to at least one example embodiment, a nonvolatile memory device is provided that includes a cell array including a main area and a buffer area configured to temporarily store pages to be stored in the main area; a page buffer configured to perform a data write operation or a data read operation on the main and buffer areas; and an on-chip randomizer configured to randomize data stored in the page buffer based on an address provided from outside the memory device.

According to at least one example embodiment, a method of operating a nonvolatile memory device may include reading first data from a first memory area of the memory device, the first memory area being configured to buffer data to be written in a second memory area of the memory device; storing the first data in a page buffer of the memory device; receiving an address indicating a location in the second memory area at which to store the first data; generating randomized data by randomizing bits of the first data based on the received address; and storing the randomized data in the second memory at the location indicated by the received address.

### BRIEF DESCRIPTION OF THE FIGURES

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a diagram for describing an example of an address scramble method applied to a multi-level memory device according to at least one example embodiment.

FIG. 2 is a diagram illustrating threshold voltage distributions varied when a program operation is carried out according to 3-step programming to store 3-bit data in each memory cell.

FIG. 3 is a block diagram schematically illustrating a nonvolatile memory device according to at least one example embodiment.

FIG. 4 is a block diagram schematically illustrating a page buffer and an on-chip randomizer according to at least one example embodiment.

FIG. 5 is a block diagram schematically illustrating an on-chip randomizer according to at least one example embodiment.

FIG. 6 is a diagram illustrating a random sequence generator in FIG. 5.

FIG. 7 is a block diagram schematically illustrating a main program method of a nonvolatile memory device according to at least one example embodiment.

FIG. 8 is a flowchart describing an operating procedure according to an embodiment of FIG. 7.

FIG. 9 is a block diagram schematically illustrating a main program method of a nonvolatile memory device according to at least one example embodiment.

FIG. 10 is a flowchart describing an operating procedure according to an embodiment of FIG. 8.

FIG. 11 is a block diagram schematically illustrating a memory system according to at least one example embodiment.

FIG. 12 is a timing diagram illustrating a write command sequence provided to a nonvolatile memory device from a memory controller in FIG. 11.

FIGS. 13A and 13B are timing diagrams describing embodiments of an on-chip randomizing operation.

FIG. 14 is a block diagram illustrating a main memory region in FIG. 3 according to at least one example embodiment.

FIG. 15 is a top view of one of memory blocks in FIG. 14.

FIG. 16 is a cross-sectional view taken along a line I-I′ in FIG. 15.

FIG. 17 is a block diagram illustrating a user device including a solid state disk according to at least one example embodiment.

FIG. 18 is a block diagram illustrating a memory system according to at least one example embodiment.

FIG. 19 is a block diagram illustrating a data storage device according to still at least one example embodiment.

FIG. 20 is a block diagram schematically illustrating a computing system including a flash memory device according to at least one example embodiment.

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

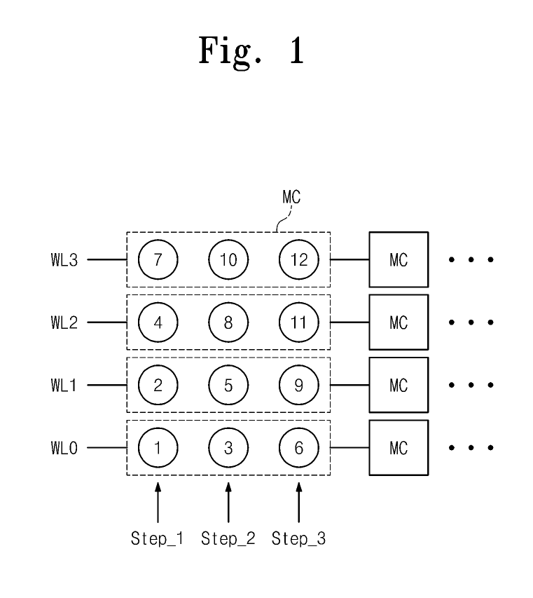

FIG. 1 is a diagram for describing an example of an address scramble method applied to a multi-level memory device according to at least one example embodiment.

With an increase in the number of data bits stored in each memory cell, it is increasingly difficult to secure the reliability of a memory device storing multi-bit (or, multi-level) data, which is referred to as a multi-level memory device, hereinafter. A representative one of factors causing degradation of the reliability may be a variation in threshold voltages due to the coupling between adjacent memory cells. For example, a threshold voltage of a previously programmed memory cell may be varied due to the coupling caused when a memory cell adjacent to a programmed memory cell is programmed. An address scramble manner may be applied to the multi-level memory device to effectively manage such coupling.

An address scramble manner will be described under the assumption that 3-bit data is stored in one memory cell. For ease of illustration, in FIG. 1, there are illustrated only four word lines WL0 to WL3. A plurality of memory cells MC is connected with each word line.

First of all, there may be performed a first step program operation step_1 in which lower 2-bit data is stored to each memory cell in a first word line WL0. That is, during the first step program operation, 2-page data may be stored in the memory cells connected with the first word line WL0. This is marked by \textcircled{1} in FIG. 1. Then, a first step program operation may be performed with respect to memory cells connected with a second word line WL1. This is marked by \textcircled{2} in FIG. 1.

After the first step program operation is performed with respect to memory cells connected with the second word line WL1, a second step program operation may be carried out with respect to the first word line WL0 which is placed below the second word line WL1 and in which lower 2-bit data and upper 1-bit data are programmed. This is marked by \textcircled{3} in FIG. 1. Following the second step program operation of memory cells connected with the first word line WL0, the first step program operation may be performed with respect to a third word line WL2. This is marked by \textcircled{4} in FIG. 1.

After the first step program operation for the third word line WL2, there may be executed the second step program operation during which upper 1-bit data is stored in memory cells that are connected with the second word line WL1 and store the lower 2-bit data. This is marked by \textcircled{5} in FIG. 1A.

After the second step program operation is performed with respect to memory cells connected with the second word line WL1, there may be performed a third step program operation on memory cells connected with the first word line WL0. This is marked by \textcircled{6} in FIG. 1. Afterwards, the first step, second step, and third step program operations may be performed sequentially according to the above-described program order (refer to FIG. 1). A manner in which word lines are selected according to the program order described in FIG. 1 may be referred to as an address scramble manner. It is well understood that an address scramble manner is not limited to this disclosure.

If the first step program operation and the second step program operation are completed, threshold voltage distributions (e.g., 2^{N} threshold voltage distributions) respectively corresponding to N-bit data (N being an integer of 2 or more) are all formed. Although all threshold voltage distributions are formed upon completion of the second step program operation, margins between threshold voltage distributions may be insufficient to distinguish threshold voltage distributions exactly. The third step program operation may be carried out to secure margins sufficient to distinguish threshold voltage distributions exactly. The third step program operation may be executed to narrow a width of each threshold voltage distribution. During the third step program operation, verification voltages may be used which are higher by a reference or predetermined voltage than verification voltages of threshold voltage distributions used at the second step program operation. It is possible to reduce the coupling between adjacent memory cells through the above-described program manner, which is referred to as a reprogram method/algorithm.

In example embodiments, the above-described reprogram method for 3-bit data, that is, the first step programming, second step programming, and third step programming may be applied to a reprogram method of 2-bit data and 4-bit data. An address scramble method was described using the case that lower 2-bit data is programmed at a first step step_1 and 3-bit data is programmed at each of a second step step_2 and a third step step_3. In view of the number of threshold voltage states, four states may be programmed at the first step step_1 and eight states may be programmed at each of the second and third steps step_2 and step_3. This may be referred to as a 4-8-8 program manner. However, according to at least one example embodiment, other manners of programming may be used. For example, the 8 states representing 3-bit data can all be programmed at the first step step_1. This may be referred to as a 8-8-8 program manner. Alternatively, a program process forcing the most interference to peripheral cells can be executed at the first step step_1. This may be referred to as a 5-8-8 program manner.

With the reprogram method, it may be necessary to retain data using other memory cells until there is completed the third step program operation for a selected word line. For example, the first step program operation may be carried out depending upon data provided to a multi-bit memory device from a memory controller, and the second step program operation may be executed depending upon data stored through the 1-step program operation and data provided from the memory controller. The third step program operation may be performed depending upon data stored through the first step and second step program operations.

But, as described above, it may be difficult to exactly read data stored through the first step and second step program operations. This means that data necessary for the third step program operation must be provided to the multi-bit memory device from the memory controller. For this reason, the memory controller may necessitate retaining data stored in memory cells in an arbitrary word line until there is completed the fine program operation for the arbitrary word line. This means that a large buffer memory is provided to the memory controller in order to retain data needed for the third step program operation.

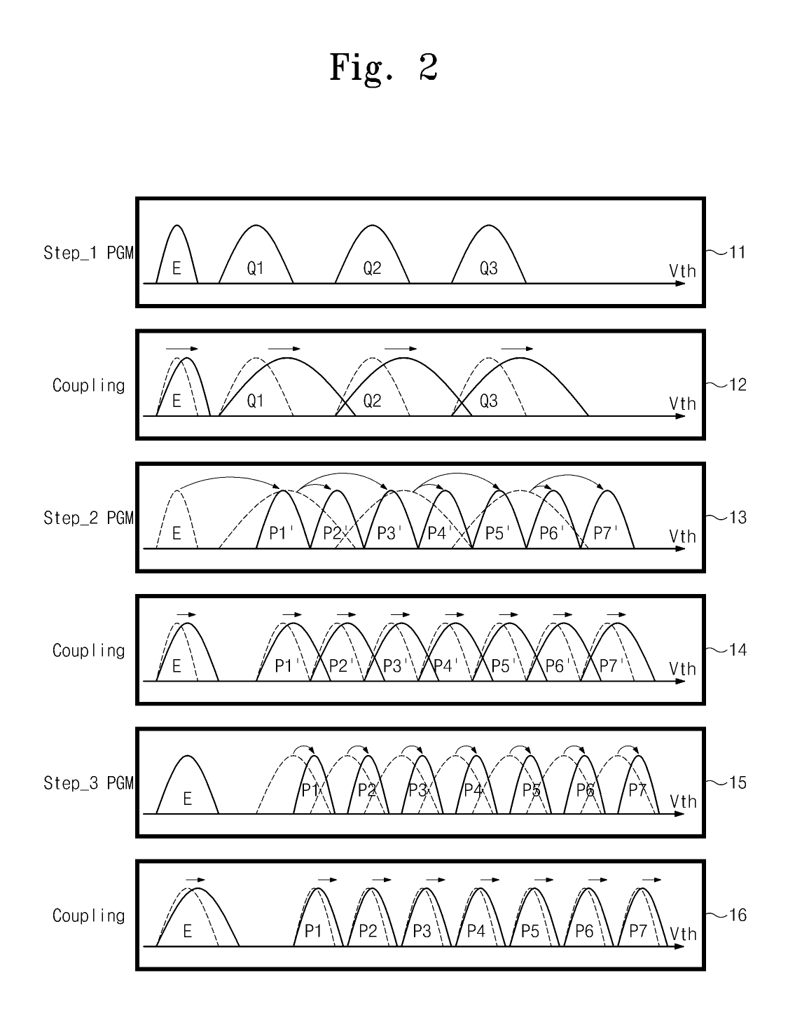

FIG. 2 is a diagram illustrating threshold voltage distributions varied when a program operation is carried out according to 3-step programming to store 3-bit data in each memory cell.

Firstly, 2-page data (i.e., first and second page data) may be stored in memory cells of a selected word line (e.g., WL0 in FIG. 1). At this time, as illustrated in a box 11 of FIG. 2, memory cells in a threshold voltage distribution corresponding to an erase state E may be programmed to have threshold voltages in threshold voltage distributions each corresponding to program states Q1, Q2, and Q3, based on data to be programmed.

As described above, a second step program operation of 1-step programmed memory cells in a selected word line WL0 may be executed after a first step program operation of memory cells in an adjacent word line WL1. At this time, as illustrated in a box 12 of FIG. 2, distributions of 1-step programmed memory cells in the word line WL0 may widen due to the coupling caused when memory cells in the adjacent word line WL1 are programmed.

Then, 1-page data (i.e., third page data) may be stored in memory cells of the selected word line WL0. At this time, as illustrated in a box 13 of FIG. 2, memory cells in a threshold voltage distribution corresponding to each state may be programmed to have threshold voltages in corresponding threshold voltage distributions. For example, memory cells in a threshold voltage distribution corresponding to an erase state E may be programmed to have threshold voltages in a threshold voltage distributions corresponding to a program state P1′, based on data to be programmed. Memory cells in a threshold voltage distribution corresponding to a program state Q1 may be programmed to have threshold voltages in threshold voltage distributions respectively corresponding to program states P2′ and P3′, based on data to be programmed. Memory cells in a threshold voltage distribution corresponding to a program state Q2 may be programmed to have threshold voltages in corresponding threshold voltage distributions to program states P4′ and P5′, based on data to be programmed. Memory cells in a threshold voltage distribution corresponding to a program state Q3 may be programmed to have threshold voltages in corresponding threshold voltage distributions to program states P6′ and P7′, based on data to be programmed.

As described above, a third step program operation of 2-step programmed memory cells in a selected word line WL0 may be executed after a first step program operation and a second step program operation on adjacent word lines (e.g., WL2 and WL1). At this time, as illustrated by a box 14 of FIG. 2, distributions of 2-step programmed memory cells in the word line WL0 may widen due to the coupling caused when memory cells in the adjacent word lines WL2 and WL1 are programmed. For this reason, it is difficult to exactly read data from 2-step programmed memory cells.

Memory cells in the word line WL0 may be programmed to have final threshold voltage distributions P1 to P7 as illustrated in a box 15 of FIG. 2. This operation may be referred to as a third step program operation. As described above, the third step program operation may necessitate previously programmed data (e.g., first to third page data). Since it is difficult to read previously programmed data from memory cells in the word line WL0, the third step program operation will be performed based on data provided from a memory controller (or, data maintained by a memory device).

As illustrated in a box 16 of FIG. 2, distributions of 3-step programmed memory cells may widen due to the coupling caused when memory cells in adjacent word lines are programmed. Afterwards, a first step program operation, a second step program operation, and a third step program operation on each word line will be performed according to a program order (or, sequence) described in FIG. 1, which will be executed in the same manner as described in FIG. 2.

Herein, the first step and second step programming may be referred to as coarse programming in which programming is schematically performed considering distribution expansion. On the other hand, the third step programming may be referred to fine programming which is executed to manage a distribution of memory cells tightly. Program voltages (e.g., increment ΔV) or verification voltages used at the coarse programming step and the fine programming step may differentiate.

Likewise, there was described the case that lower 2-bit data is programmed at a first step step_1 and 3-bit data is programmed at each of a second step step_2 and a third step step_{—}3 (4-8-8). However, according to at least one example embodiment, other manners of programming may be used. Other manners include, for example, the 8-8-8 program manner, in which 3-bit data all can be programmed at the first step step_1, and the 5-8-8 program manner in which five states are programmed at the first step step_1.

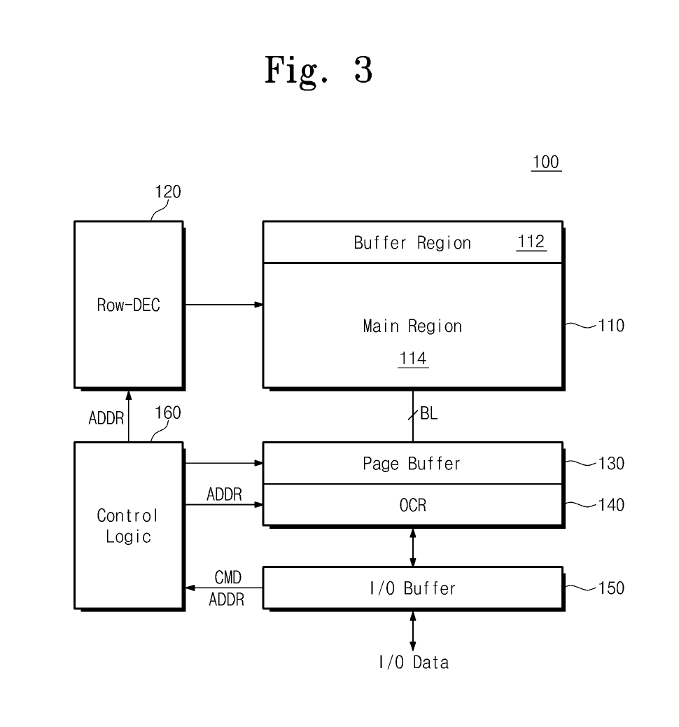

FIG. 3 is a block diagram schematically illustrating a nonvolatile memory device according to at least one example embodiment. Referring to FIG. 3, a nonvolatile memory device 100 may include a cell array 110, a row decoder 120, a page buffer 130, an on-chip randomizer 140, an input/output buffer 150, and control logic 160.

The cell array 110 may be connected to the row decoder 120 via word lines or selection lines SSL and GSL. The cell array 110 may be connected to the page buffer 130 via bit lines BL. The cell array 110 may include a plurality of NAND cell strings. In particular, a memory region of the cell array 110 may be divided into a buffer region 112 and a main region 114. At a program operation, after data may be written in the buffer region 112, it may be programmed in the main region 114. An operation of programming data in the buffer region 112 may be referred to as a buffer program operation, and an operation of programming data in the main region 114 may be referred to as a main program operation.

The main program operation may be executed according to address information associated with data stored in the buffer region 112. In example embodiments, the minimum program unit of the buffer region 112 and the minimum program unit of the main region 114 may be decided variously according to a program manner, the number of data bits being stored in a memory cell, and the like. According to at least one example embodiment, the minimum program unit of the buffer region 112 may be different from the minimum program unit of the main region 114.

In example embodiments, memory blocks of the cell array 110 may be divided at least into the buffer region 112 and the main region 114. Herein, the memory regions 112 and 114 may be divided logically, not physically. That is, the memory regions 112 and 114 can be logically variable. Memory blocks in the buffer region 112 may be programmed in a manner different from memory blocks in the main region 114. For example, the memory blocks in the buffer region 112 may be programmed in a single-bit program manner (hereinafter, referred to as an SLC program manner), and the memory blocks in the main region 114 may be programmed in a multi-bit program manner (hereinafter, referred to as an MLC program manner).

In other example embodiments, memory blocks in the buffer and main regions 112 and 114 may be programmed in the MLC program manner. For example, the memory blocks in the main region 114 may be programmed in the above-described N-step program manner. In other words, each of memory cells in the buffer region 112 may store 1-bit data, and each of memory cells in the main region 114 may store N-bit data (N being an integer of 3 or more). Further, each of memory cells of the buffer region 112 may store data bits the number of which is less than that of the N-bit data stored in each of memory cells of the main region 114.

The row decoder 120 may select one of memory blocks in the cell array 110 in response to a row address ADDR. The row decoder 120 may select one of word lines in the selected memory block. The row decoder 120 may transfer a word line voltage to word lines of the selected memory block. The row decoder 120 may transfer selection signals to selection lines (e.g., SSL or GSL) of the selected memory block. The row decoder 120 may transfer a program voltage and a verification voltage to a selected word line and a pass voltage to an unselected word line.

The page buffer 130 may operate as a write driver or a sense amplifier according to a mode of operation. At a program operation, the page buffer 130 may provide a bit line voltage corresponding to data to be programmed to a bit line of the cell array 110. At a read operation, the page buffer 130 may sense data stored in a selected memory cell via a bit line. The page buffer 130 may latch the sensed data to output it to an external device.

The on-chip randomizer 140 may be configured to randomize data to be programmed in the cell array 110. The on-chip randomizer 140 may be configured to de-randomize data that is stored in the page buffer 130 after sensed from the cell array 110. In particular, the on-chip randomizer 140 according to at least one example embodiment may perform a randomizing operation on a plurality of pages read from the buffer region 112. When a program command on the main region 114 is received, a target address may be provided from the outside. The on-chip randomizer 140 may acquire a seed from the target address provided from the outside. The on-chip randomizer 140 may generate a random sequence based on the seed. The on-chip randomizer 140 may randomize a plurality of pages to be stored in a target region using the random sequence. Afterwards, the randomized pages may be programmed in the target region.

The on-chip randomizer 140 may perform a de-randomizing operation at a read operation. Data read out from the main region 114 may be first latched by the page buffer 130. The latched data may be de-randomized according to a random sequence used at a randomizing operation of the on-chip randomizer 140. The de-randomized data may be output to an external device via the input/output buffer 150.

The input/output buffer 150 may transfer write data input at a program operation to the page buffer 130. The input/output buffer 150 may output read-out data provided from the page buffer 130 to an external device at a read operation. The input/output buffer 150 may transfer input addresses or commands to the control logic 160, the row decoder 120, or the on-chip randomizer 140.

The control logic 160 may control the page buffer 130 and the on-chip randomizer 140 in response to a command CMD and an address ADDR provided from the input/output buffer 150. The control logic 160 may perform a command on a selected memory region in response to a write command, a read command, and an erase command provided via the input/output buffer 150.

According to at least one example embodiment, the nonvolatile memory device 100 may include the on-chip randomizer 140. In particular, at a main program operation, a randomizing operation on program data may be executed in response to an input target address. Randomized data may be programmed in a target region. A randomizing operation according to at least one example embodiment may reduce a variation in threshold voltages of memory cells generated due to the word line coupling. In other words, since states of memory cells are distributed uniformly, a level of the word line coupling between memory cells may be reduced relatively compared with that before data randomization. That is, a variation in threshold voltages of memory cells may be suppressed. This may mean that a read margin, that is, the reliability is improved.

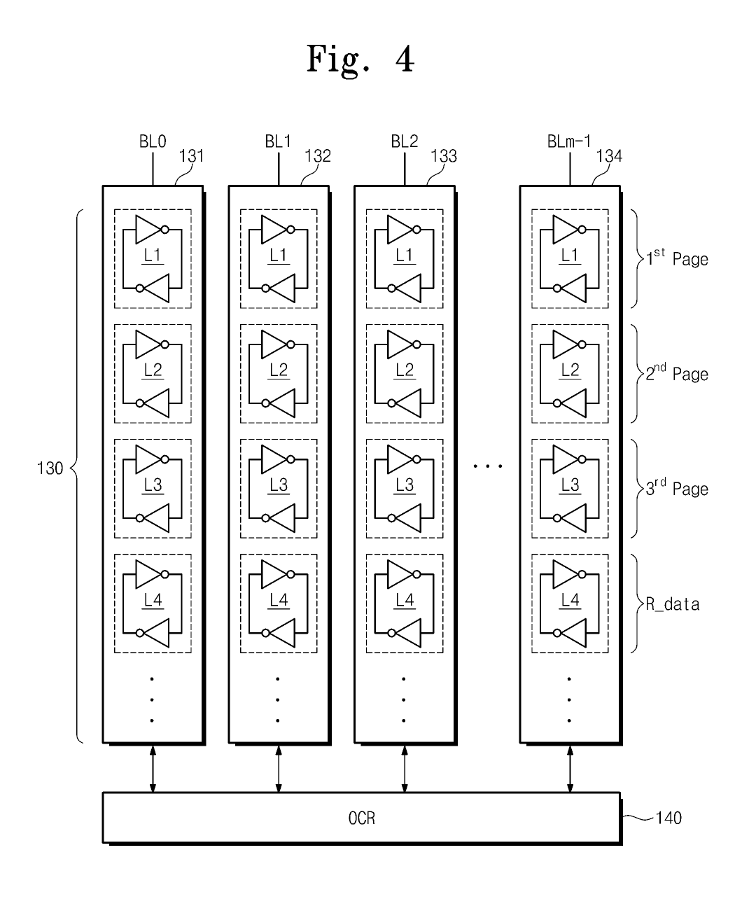

FIG. 4 is a block diagram schematically illustrating a page buffer and an on-chip randomizer according to at least one example embodiment. Referring to FIG. 4, a page buffer 130 may include a plurality of page buffer circuits 131 to 134 that are connected to bit lines BL0 to BLm−1, respectively. An on-chip randomizer 140 may randomize or de-randomize data stored in the page buffer circuits 131 to 134.

Each of the page buffer circuits 131 to 134 may include a plurality of latches L1, L2, L3, L4, etc. At a buffer program operation or a main program operation, data to be programmed may be loaded onto latches of the page buffer circuits 131 to 134. For the main program operation, a plurality of page data stored in a buffer region 112 may be sensed, and the sensed page data may be latched by latches. For example, a first page sensed from the buffer region 112 may be stored in first latches L1 of the page buffer circuits 131 to 134. A second page sensed from the buffer region 112 may be stored in second latches L2 of the page buffer circuits 131 to 134. A third page sensed from the buffer region 112 may be stored in third latches L3 of the page buffer circuits 131 to 134. Randomization information R_data for a randomizing operation may be stored in fourth latches L4 of the page buffer circuits 131 to 134.

If reading on the buffer region 112 is completed, a program command on a plurality of pages of a target region in a main region 114 may be received. The program command on the target region may include a target address on the target region. If the target address is input, the on-chip randomizer 140 may generate a seed corresponding to the target address. The on-chip randomizer 140 may generate a random sequence RS using the seed. The on-chip randomizer 140 may store the seed or the random sequence in the fourth latches L4 of the page buffer circuits 131 to 134 as the randomization information R_data.

The on-chip randomizer 140 may perform a randomizing operation on each of a plurality of pages based on the random sequence RS. Latches L1, L2, and L3 of each of the page buffer circuits 131 to 134 may be set up with the randomized data. Afterwards, the page buffer 130 may program the plurality of pages in the target region according to a manner described in relation to FIGS. 1 and 2.

Herein, a plurality of pages stored in the buffer region 112 may be data randomized at a buffer program operation. In this case, after the plurality of pages is sensed, a de-randomizing operation on each page may be executed.

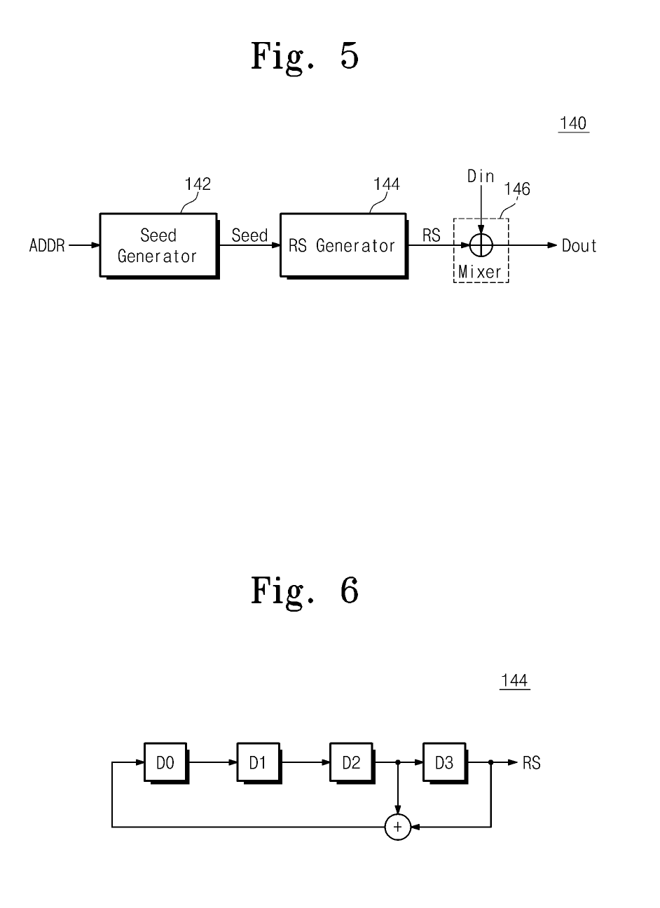

FIG. 5 is a block diagram schematically illustrating an on-chip randomizer according to at least one example embodiment. Referring to FIG. 5, an on-chip randomizer 140 may include a seed generator 142, a random sequence generator 144, and a mixer 146.

The seed generator 142 may generate a seed used to randomize each of a plurality of pages, based on a target address ADDR. For example, a seed on each of pages to be written in a target region can be provided from a lookup table so as to be selected according to a relative location within a block. In this case, the seed generator 142 may acquire a seed on each page from a lookup table, based on the target address ADDR. If a seed corresponding to a page is generated, the seed generator 142 may provide the random sequence generator 144 with the seed.

The random sequence generator 144 may generate a random sequence RS using a seed provided from the seed generator 142. The random sequence generator 144 may generate a random sequence RS using an input seed as an initial seed value. For example, the random sequence generator 144 may be formed of a linear feedback shift register (LSFR) that operates in the Fibonacci configuration.

The mixer 146 may mix the random sequence RS generated by the random sequence generator 144 for a randomizing operation with input data. For example, bits of the random sequence RS may be mixed with bits of the input data Din to generate output data Dout using; for example, an XOR operation between the random sequence RS and the input data Din. Herein, the input data Din may be a plurality of page data stored in a page buffer 130. Latches L1, L2, and L3 of the page buffer 130 may be reconfigured by randomized data Dout output from the mixer 146.

FIG. 6 is a diagram illustrating a random sequence generator in FIG. 5. In FIG. 6, there is illustrated a random sequence generator 144 that generates a random sequence according to the Fibonacci configuration formed of four flip-flops D0 to D3. The random sequence generator 144 may be configured to satisfy the following polynomial equation.

g(X)=X⁴+X+1 (1)

That is, the random sequence generator 144 may be formed of a linear feedback shift register (LFSR) including a plurality of flip-flops. Herein, binary values stored in the flip-flops D0 to D3 may form a seed. A stream of bits output according to toggling of a clock may constitute the random sequence RS.

It is assumed that initial values of the flip-flops D0 to D3 in the random sequence generator 144 are “1000”. Values stored in the flip-flops D0 to D3 after 15 clock cycles may be equal to the initial values. Afterwards, values of the flip-flops D0 to D3 may be set up in the same manner as described above. At this time, a stream of bits output from the flip-flop D3 may be a random sequence. The random sequence generator 144 is not limited to the Fibonacci configuration. It is well understood that the random sequence generator 144 is changed or modified variously.

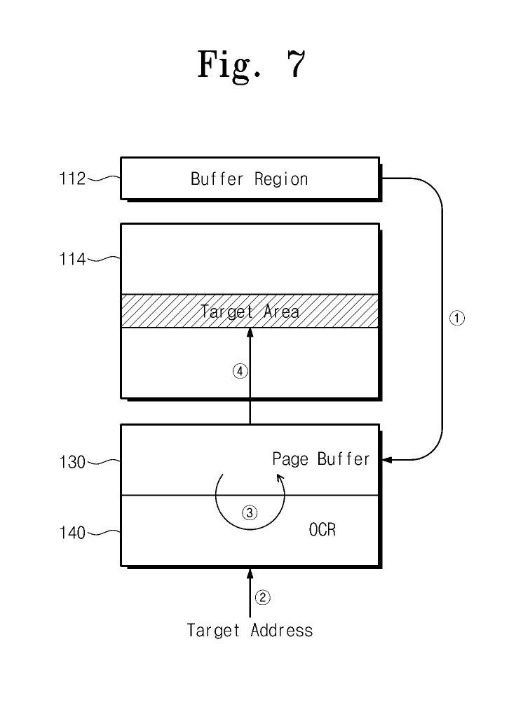

FIG. 7 is a block diagram schematically illustrating a main program method of a nonvolatile memory device according to at least one example embodiment. Referring to FIG. 7, at a main program operation, a nonvolatile memory device 100 may perform a randomizing operation on program data in response to a target address. This will be more fully described below.

A read operation on a buffer area 112 may be first performed to program a plurality of pages stored in the buffer area 112 at a target area of a main area 114. Thus, a page buffer 130 may sense a plurality of pages stored in the buffer area 112. This operation may be illustrated by a data path (\textcircled{1}). Sensed page data may be stored and retained in latches L1, L2, and L3 of the page buffer 130.

If reading on the buffer area 112 is completed, a write command directing writing of the read pages into the main area 114 may be provided from an external device. The write command may include a target address corresponding to the target area. An on-chip randomizer 140 may be provided with the target address which is used to randomize a plurality of pages stored in latches. This operation may be illustrated by an arrow (\textcircled{2}).

If the target address is provided, the on-chip randomizer 140 may randomize a plurality of pages stored in the page buffer 130 based on the target address. This operation may be illustrated by an arrow (\textcircled{3}). The on-chip randomizer 140 may generate a seed for a randomizing operation. The on-chip randomizer 140 may generate a random sequence RS using the seed. The on-chip randomizer 140 may randomize the plurality of pages using the random sequence RS.

If the plurality of pages is randomized, the page buffer 130 may program the plurality of pages in the target area. The plurality of pages programmed in the target area may be programmed in memory cells of the target area in a manner described in relation to FIG. 2. This operation may be illustrated by an arrow (\textcircled{4}).

The on-chip randomizer 140 may randomize a plurality of pages based on a target address on the main area 114. Thus, the plurality of pages randomized using the target address may be programmed in the target area of the main area 114.

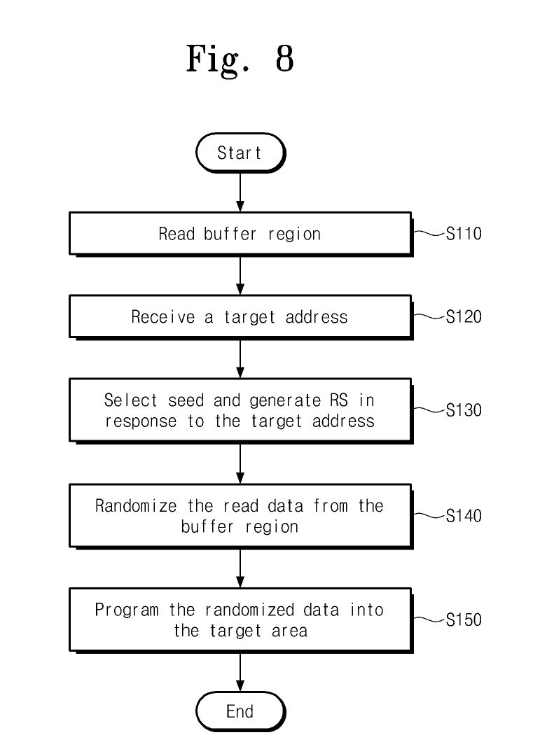

FIG. 8 is a flowchart describing an operating procedure according to an embodiment of FIG. 7. Below, a read operation of a nonvolatile memory device according to at least one example embodiment will be more fully described with reference to accompanying drawings.

In operation S110, a buffer read operation may be performed on a plurality of pages stored in a buffer area 112. A read command may be provided from an external device to read a plurality of pages stored in the buffer area 112. At the buffer read operation, pages sensed from the buffer area 112 may be sequentially stored in latches L1, L2, and L3 of respective page buffer circuits in a page buffer 130. That is, a first page stored in the buffer area 112 may be stored in first latches L1 of page buffer circuits 131 to 134 in the page buffer 130. A second page stored in the buffer area 112 may be stored in second latches L2 of the page buffer circuits 131 to 134 in the page buffer 130. A third page stored in the buffer area 112 may be stored in third latches L3 of the page buffer circuits 131 to 134 in the page buffer 130.

In operation S120, a nonvolatile memory device 100 may receive a target address provided from an external device. The target address received according to a main program command may be stored in an input/output buffer 150, and may be decoded or selectively extracted by control logic 160 so as to be provided to an on-chip randomizer 140.

In operation S130, the on-chip randomizer 140 may generate a seed from the provided target address. For example, a seed generator 142 (refer to FIG. 5) may generate a seed corresponding to the target address. The seed may be provided via means such as a lookup table. The generated seed may be provided to a random sequence generator 144 (refer to FIG. 5). Herein, the seed may be different according to pages stored in the page buffer 130. If the seed is generated, it can be stored in extra latches of the page buffer 130.

A random sequence generator 144 may generate a random sequence RS used to randomize a plurality of pages. Herein, the random sequence generator 144 may be a random sequence generating circuit using the above-described Fibonacci configuration.

In operation S140, the plurality of pages stored in the page buffer 130 may be randomized. That is, each of pages stored in latches of the page buffer 130 may be sequentially mixed with the random sequence RS. For example, bits of each page may be randomized by an exclusive-OR operation with bits of the random sequence RS. A bit value of each page stored in latches of the page buffer 130 may be toggled or remained after a randomizing operation.

In operation S150, the randomized pages may be programmed in the main area 114. The plurality of pages may be programmed in a target area selected by the target address via the page buffer 130. For example, the plurality of pages may be programmed in memory cells of the target area in a manner described in relation to FIG. 2.

With the above-described manner, a plurality of pages of the buffer area 112 latched in the page buffer 130 by a buffer read operation may be randomized by the on-chip randomizer 140. In particular, a randomizing operation may start at an input of a target address. This may be because a seed for a randomizing operation is selected or generated in response to the target address.

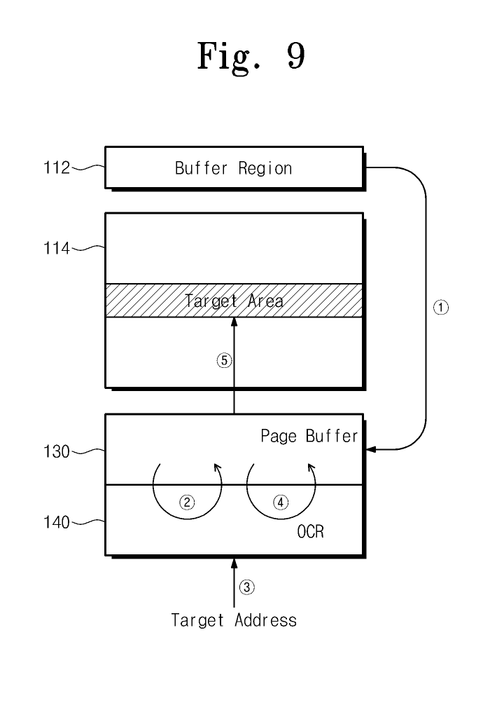

FIG. 9 is a block diagram schematically illustrating a main program method of a nonvolatile memory device according to at least one example embodiment. Referring to FIG. 9, a nonvolatile memory device 100 may be configured to perform a randomizing operation even at a buffer program operation. Thus, a de-randomizing operation may be performed at the buffer read operation. A randomizing operation on program data may be carried out in response to a target address at a main program operation.

Although not shown in FIG. 9, a plurality of pages randomized may be stored in a buffer area 112. Thus, at the buffer program operation, each page may be randomized by a random sequence generated by the on-chip randomizer 130. At this time, a random sequence RS may be generated using a seed that is generated according to a page address of the buffer area 112.

A plurality of pages stored in the buffer area 112 may be sensed and latched by the page buffer 130 to execute a main program operation on the plurality of pages. For this, a buffer read command and a page address may be provided from an external device. The plurality of pages stored in the buffer area 112 may be sensed by the page buffer 130 in response to the input buffer read command and page address. This operation may be illustrated by an arrow (\textcircled{1}). The sensed page data may be stored and retained in latches L1, L2, and L3 of the page buffer 130.

A plurality of pages stored in the buffer area 112 may be data encoded by a randomizing operation. Thus, a de-randomizing operation on the randomized data may be required. The de-randomizing operation on the plurality of pages may be executed by the on-chip randomizer 140. A seed on each of the plurality of pages may be required to perform a de-randomizing operation on the plurality of pages provided for a randomizing operation. The seed can be generated from a page address included in the buffer read command. It is possible to generate a random sequence RS corresponding to each page from a seed on each page. The on-chip randomizer 140 may generate a random sequence RS to de-randomize a plurality of pages stored in latches L1, L2, and L3 of the page buffer 130. This operation may be illustrated by a data path (\textcircled{2}).

After a de-randomizing operation on a plurality of pages latched in the page buffer 130 by the buffer read operation, a program command directing programming of a plurality of pages in a main area 114 may be provided from the external device. The program command may include a target address corresponding to a target area. The on-chip randomizer 140 may be provided with the target address for performing a randomizing operation on a plurality of pages stored in latches. This operation may be illustrated by an arrow (\textcircled{3}).

If the target address is provided, the on-chip randomizer 140 may randomize a plurality of pages stored in the page buffer 130 based on the target address. This operation may be illustrated by an arrow (\textcircled{4}). The on-chip randomizer 140 may generate a seed for a randomizing operation. The on-chip randomizer 140 may generate a random sequence RS using the seed. The on-chip randomizer 140 may randomize a plurality of pages using the random sequence RS, respectively.

After a randomizing operation on a plurality of pages, the page buffer 130 may program the plurality of pages randomized in the target area. Programming of the plurality of pages in the target area may be performed in a manner described in relation to FIG. 2. This operation may be illustrated by an arrow (\textcircled{5}).

The on-chip randomizer 140 may randomize a plurality of pages based on a target address on a main area from the external device. Thus, a target address is input, and randomized pages may be programmed in a target area of the main area 114.

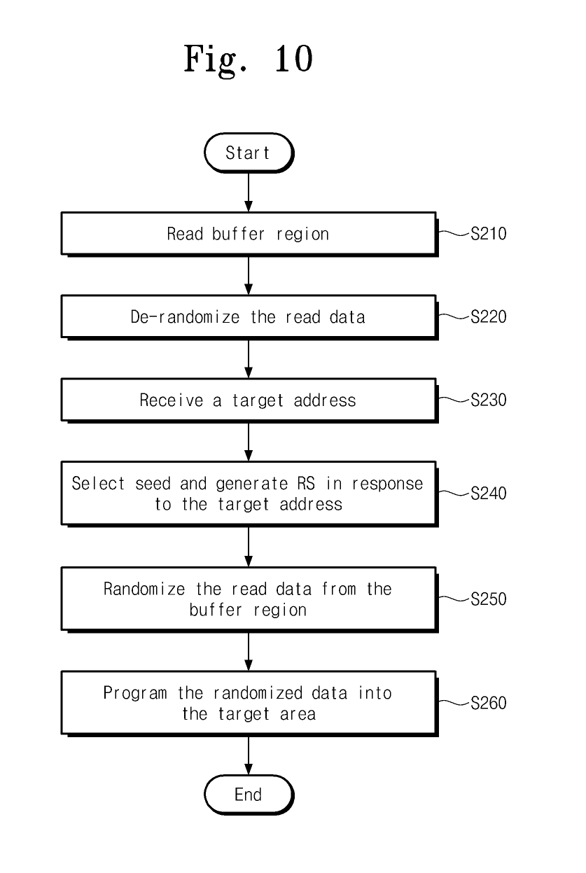

FIG. 10 is a flowchart describing an operating procedure according to an embodiment of FIG. 8. Below, a read operation of a nonvolatile memory device according to at least one example embodiment will be more fully described with reference to accompanying drawings.

In operation 5210, a buffer read operation may be performed on a plurality of pages stored in a buffer area 112. At this time, a plurality of pages stored in the buffer area 112 may be data randomized at a buffer program operation. A read command may be provided from an external device to read a plurality of pages stored in the buffer area 112. At the buffer read operation, pages sensed from the buffer area 112 may be sequentially stored in latches L1, L2, and L3 of respective page buffer circuits in a page buffer 130. That is, a first page stored in the buffer area 112 may be stored in first latches L1 of page buffer circuits 131 to 134 in the page buffer 130. A second page stored in the buffer area 112 may be stored in second latches L2 of the page buffer circuits 131 to 134 in the page buffer 130. A third page stored in the buffer area 112 may be stored in third latches L3 of the page buffer circuits 131 to 134 in the page buffer 130.

In operation 5220, a plurality of pages latched in the page buffer 130 via the buffer read operation may be de-randomized. This operation may be executed using a page address provided at the buffer read operation. An on-chip randomizer 140 may generate a seed on each of a plurality of pages based on a page address provided at the buffer read operation. The on-chip randomizer 140 may generate a random sequence RS based on the generated seed. The on-chip randomizer 140 may de-randomize a plurality of pages stored in latches L1, L2, and L3 of the page buffer 130 using the generated random sequence RS. A bit value of each page stored in the latches L1, L2, and L3 of the page buffer 130 may be toggled or remained after the de-randomizing operation.

In operation 5230, a nonvolatile memory device 100 may receive a target address for a main program operation provided from an external device. The target address received according to a main program command may be stored in an input/output buffer 150, and may be decoded or selectively extracted by control logic 160 so as to be provided to the on-chip randomizer 140.

In operation 5240, the on-chip randomizer 140 may generate a seed from the provided target address. For example, a seed generator 142 (refer to FIG. 5) may generate a seed corresponding to the target address. The seed may be provided via means such as a lookup table. The generated seed may be provided to a random sequence generator 144 (refer to FIG. 5). Herein, the seed may be different according to pages stored in the page buffer 130. If the seed is generated, it can be stored in extra latches of the page buffer 130. Alternatively, the seed can be provided as a value on a plurality of pages latched in the page buffer 130. The generated seed can be stored in extra latches of the page buffer 130. The random sequence generator 144 may generate a random sequence RS for randomizing a plurality of pages based on the generated seed.

In operation 5250, the plurality of pages stored in the page buffer 130 may be randomized. That is, each of pages stored in latches of the page buffer 130 may be sequentially mixed with the random sequence RS. For example, bits of each page may be randomized by an exclusive-OR operation with bits of the random sequence RS. A bit value of each page stored in latches of the page buffer 130 may be toggled or remained after a randomizing operation.

In operation 5260, the randomized pages may be programmed in the main area 114. The plurality of pages may be programmed in a target area selected by the target address via the page buffer 130. For example, the plurality of pages may be programmed in memory cells of the target area in a manner described in relation to FIG. 2.

With the above-described manner, a plurality of pages of the buffer area 112 latched in the page buffer 130 by a buffer read operation may be randomized by the on-chip randomizer 140. The buffer read operation may accompany a de-randomizing operation on a plurality of pages randomized at a buffer program operation. A randomizing operation being executed at a main program operation may start at an input of a target address. This may be because a seed for a randomizing operation is selected or generated in response to the target address.

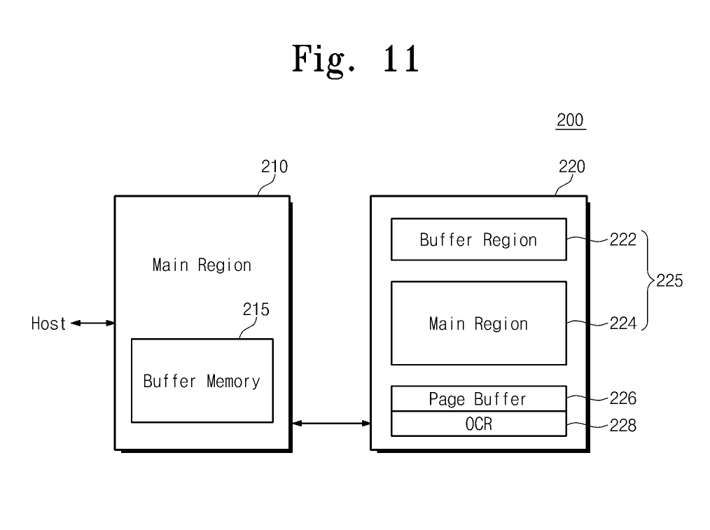

FIG. 11 is a block diagram schematically illustrating a memory system according to at least one example embodiment. Referring to FIG. 11, a memory system 200 may include a memory controller 210 and a nonvolatile memory device 220.

The memory controller 210 may be configured to control the nonvolatile memory device 220 in response to a request of a host. The memory controller 210 may provide the nonvolatile memory device 220 with a write command and an address in response to a write request of the host.

The memory controller 210 may control a program operation of the nonvolatile memory device 220 in a static scheduling manner. For example, if data (e.g., page data) of the minimum program unit on a buffer area 222 of the nonvolatile memory device 220 is stored in a buffer memory 215, the memory controller 210 may control the nonvolatile memory device 220 such that data of the minimum program unit is stored in the buffer area 222. This operation may be referred to as a buffer program operation.

The buffer program operation may be executed according to address information. If data of the minimum program unit on a main area 224 is stored in the buffer area 222, the memory controller 210 may control the nonvolatile memory device 220 such that data of the minimum program unit on the main area 224 is stored in the main area 224. This operation may be referred to as a main program operation.

The main program operation may be performed according to address information associated with data stored in the buffer area 222. The buffer program operation and the main program operation will be more fully described later. In example embodiments, the minimum program unit on the buffer area 222 and the minimum program unit on the main area 224 may be decided variously according to a program manner, a bit-per-cell number, and the like. With at least one example embodiment, the minimum program unit on the buffer area 222 may be different from the minimum program unit on the main area 224.

A size of the buffer memory 215 of the memory controller 210 may be minimized by storing data in the buffer area 222 via the buffer program operation and storing data in the main area 224 via the main program operation. In other words, it is unnecessary to retain data for a third step program operation using the buffer memory 215. For this reason, it is possible to minimize a size of the buffer memory 215 of the memory controller 210.

The nonvolatile memory device 220 may be formed of one or more memory devices. The memory controller 210 and the nonvolatile memory device 220 may constitute a memory card, a Solid State Drive (SSD), a memory stick, and the like. The nonvolatile memory device 220 may include a plurality of memory blocks, each of which has a plurality of memory cells arranged in rows and columns. Each memory cell may store multi-level (or, multi-bit) data. The memory cells may be arranged to have a two-dimensional array structure or a three-dimensional (or, vertical) array structure.

The nonvolatile memory device may be substantially equal to that described in FIG. 3. A memory array 225 of the nonvolatile memory device 220 may include a plurality of memory blocks, which are divided at least into the buffer area 222 and the main area 224. Herein, the buffer and main areas 222 and 224 may be divided logically, not physically. That is, the buffer and main areas 222 and 224 can be logically variable.

The number of memory blocks in the buffer area 222 may be variable according to the number of data bits stored in each of memory cells of the main area 224. For example, in case that memory cells in the main area 224 store N-bit data (N being an integer of 3 or more), the buffer area 222 may include at least N memory blocks. N-bit data to be stored in memory cells of the main area 224 may be stored in corresponding memory blocks of the buffer area 222, respectively.

The nonvolatile memory device 220 may include an on-chip randomizer 228 that performs a randomizing operation or a de-randomizing operation based on an address provided from an external device. The on-chip randomizer 228 may generate a seed and a random sequence RS using the address. The on-chip randomizer 228 may randomize data programmed in the buffer area 222 or the main area 224 based on the generated random sequence RS. A page buffer 226 may program randomized data in the buffer area 222 or the main area 224.

The on-chip randomizer 228 may de-randomize data read from the buffer area 222 or the main area 224. The on-chip randomizer 228 may generate a seed and a random sequence RS based on an address provided with a read command. The on-chip randomizer 228 may de-randomize data latched in the page buffer 226 using the generated random sequence RS.

The memory controller 210 may provide write-requested data to the nonvolatile memory device 220 without randomizing. The nonvolatile memory device 220 may execute a randomizing operation on data to be stored in the buffer area 222 or the main area 224 using the on-chip randomizer 228. At a read operation, the nonvolatile memory device 220 may generate a seed and a random sequence RS using an input address. The nonvolatile memory device 220 may de-randomize sensed data using the generated random sequence RS to provide it to the memory controller 210. With this configuration, it is possible to reduce the burden of the memory controller 210 on a randomizing operation that is performed to improve the integrity of data. The nonvolatile memory device 220 may randomize and de-randomize data using a high-speed on-chip randomizer 228. The randomizing operation may be performed effectively.

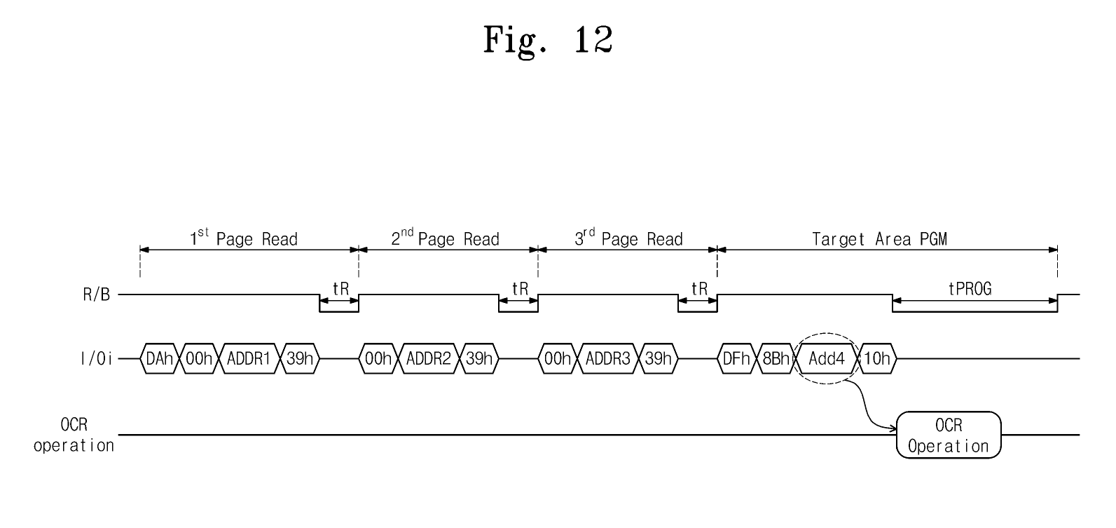

FIG. 12 is a timing diagram illustrating a write command sequence provided to a nonvolatile memory device from a memory controller in FIG. 11. Referring to FIG. 12, a memory controller 210 may provide a nonvolatile memory device 220 with a buffer read command and a main program command.

The buffer read command may be provided with respect to each of a plurality of pages stored in a buffer area 222. Herein, data read at a buffer read operation may not be output to an external device. Thus, internal read commands DAh and DFh directing a read mode may be input at start and end points of the buffer read operation, respectively. If error correction is required or in case that an output of data stored in the buffer area 222 before writing to a target area, the internal read commands DAh and DFh may be skipped.

A code DAh indicating a start of an internal read operation may be input, and a command sequence 00h-ADDR1-39h directing reading of a first page from the buffer 222 may be provided. A page buffer 226 of the nonvolatile memory device 220 may sense and latch the first page from the buffer area 222 during a read time tR. The nonvolatile memory device 220 may maintain a ready/busy signal R/B at a busy state (e.g., logical ‘L’) during a period where the page buffer 226 senses and latches the first page.

If an internal read operation on the first page is completed, the ready/busy signal R/B may transition to a ready state (e.g., logical ‘H’). Then, the memory controller 210 may provide a command sequence 00h-ADDR2-39h directing reading of a second page from the buffer 222. The page buffer 226 of the nonvolatile memory device 220 may sense and latch the second page from the buffer area 222 during the read time tR. The nonvolatile memory device 220 may maintain the ready/busy signal R/B at the busy state (e.g., logical ‘L’) during a period where the page buffer 226 senses and latches the second page.

If an internal read operation on the second page is completed, the ready/busy signal R/B may transition to a ready state (e.g., logical ‘H’). Then, the memory controller 210 may provide a command sequence 00h-ADDR3-39h directing reading of a third page from the buffer 222. The page buffer 226 of the nonvolatile memory device 220 may sense and latch the third page from the buffer area 222 during the read time tR. The nonvolatile memory device 220 may maintain the ready/busy signal R/B at the busy state (e.g., logical ‘L’) during a period where the page buffer 226 senses and latches the third page.

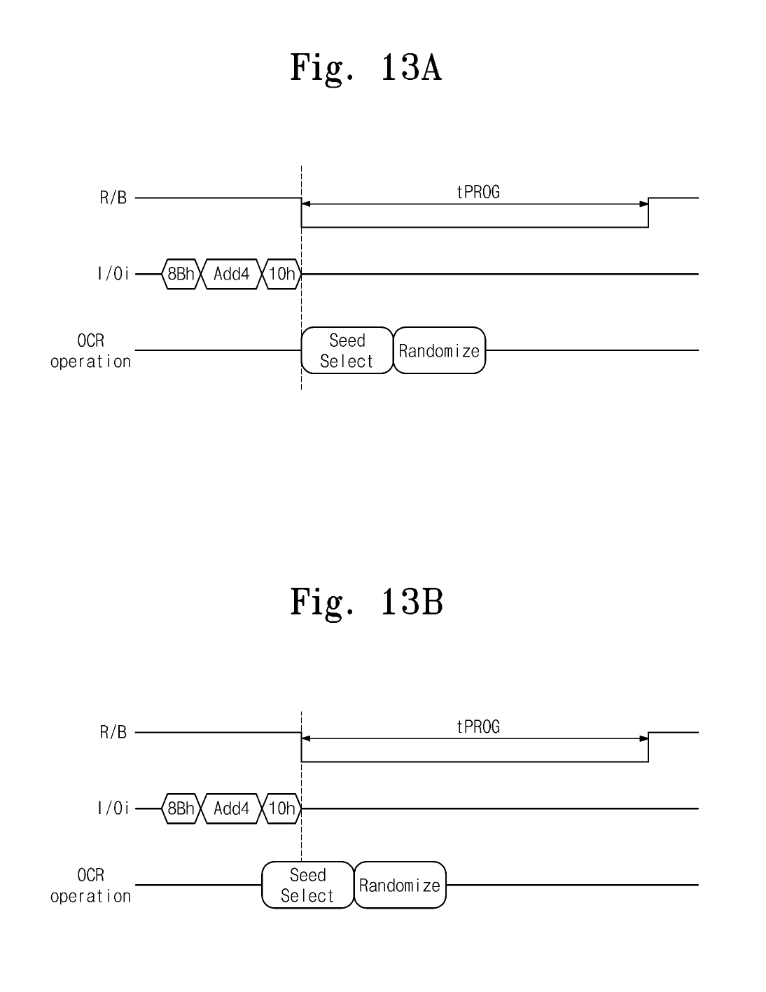

If an internal read operation on the third page is completed, the ready/busy signal R/B may transition to a ready state (e.g., logical ‘H’). Then, the memory controller 210 may sequentially provide a command DFh directing an end of the internal read operation and a command sequence 8B0h-ADDR4-10h directing a main program operation. In response to the command sequence 8Bh-ADDR4-10h, the ready/busy signal R/B may go to the busy state (e.g., logical ‘L’) during a program period tPROG, and a plurality of pages latched in the page buffer 226 may be programmed in a target area. Further, if the command sequence 8B0h-ADDR4-10h is provided, the nonvolatile memory device 220 may generate a random sequence RS from the target address ADDR4 to randomize the plurality of pages using the generated random sequence RS. That is, the nonvolatile memory device 220 may perform an On-Chip Randomizing (OCR) operation, which will be more fully described with reference to FIGS. 13A and 13B.

FIGS. 13A and 13B are timing diagrams describing embodiments of an on-chip randomizing operation. FIG. 13A shows an on-chip randomizing operation which starts after a ready/busy signal R/B transitions to a busy state (e.g., logical ‘L’) by a command sequence 8Bh-ADDR4-10h. FIG. 13B shows an on-chip randomizing operation which starts before a ready/busy signal R/B transitions to a busy state (e.g., logical ‘L’) by a command sequence 8Bh-ADDR4-10h. It is understood from an embodiment in FIG. 13B that selection/generation of a seed and generation of a random sequence is made to randomize a plurality of pages immediately when a target address ADDR4 is input.

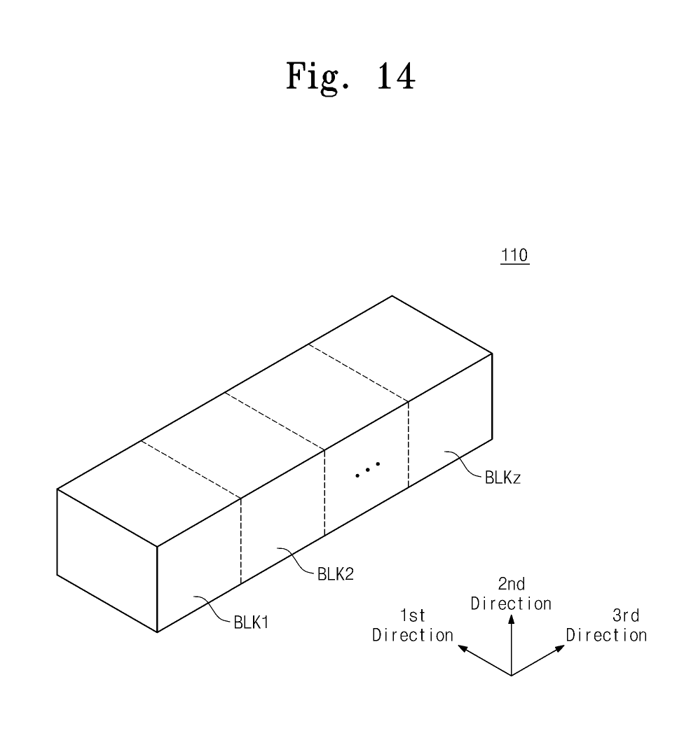

FIG. 14 is a block diagram illustrating a main memory region in FIG. 3 according to at least one example embodiment. Referring to FIG. 14, a cell array 110 may include a plurality of memory blocks BLK1 to BLKz that correspond to a buffer region 112 or a main region 114. Each of the memory blocks BLK1 to BLKz may be formed to have a three-dimensional structure (or, a vertical structure). For example, each of the memory blocks BLK1 to BLKz may include structures extending along first to third directions. Each of the memory blocks BLK1 to BLKz may include a plurality of NAND cell strings extending along the third direction.

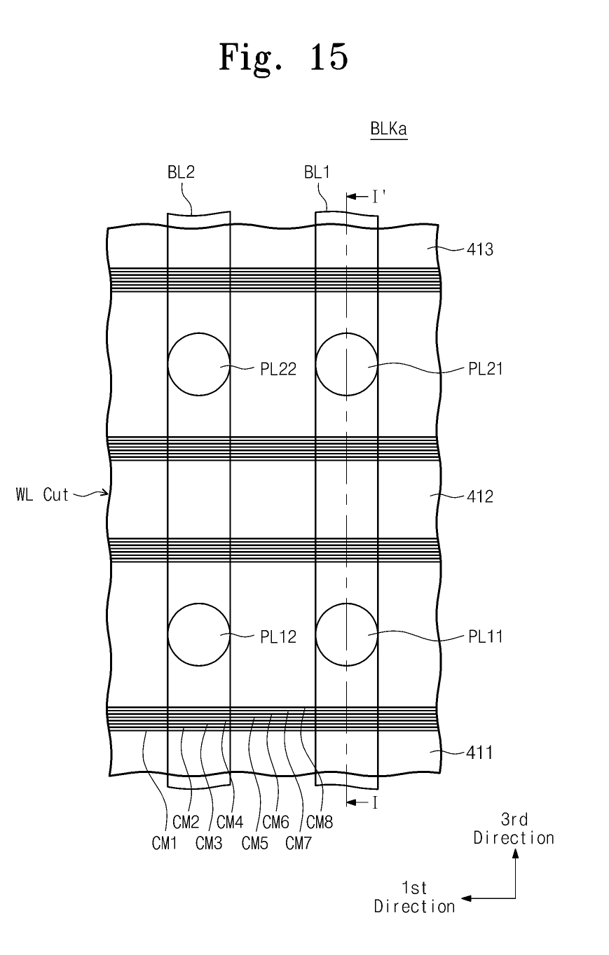

Each NAND cell string may be coupled with a bit line BL, a string selection line SSL, a plurality of word lines WL, a ground selection line GSL, and a common source line CSL. That is, each memory block may be connected with a plurality of bit lines BL, a plurality of string selection lines SSL, a plurality of ground selection lines GSL, a plurality of word lines WL, and a common source line CSL. The memory blocks BLK1 to BLKz will be more fully described with reference to FIG. 15.

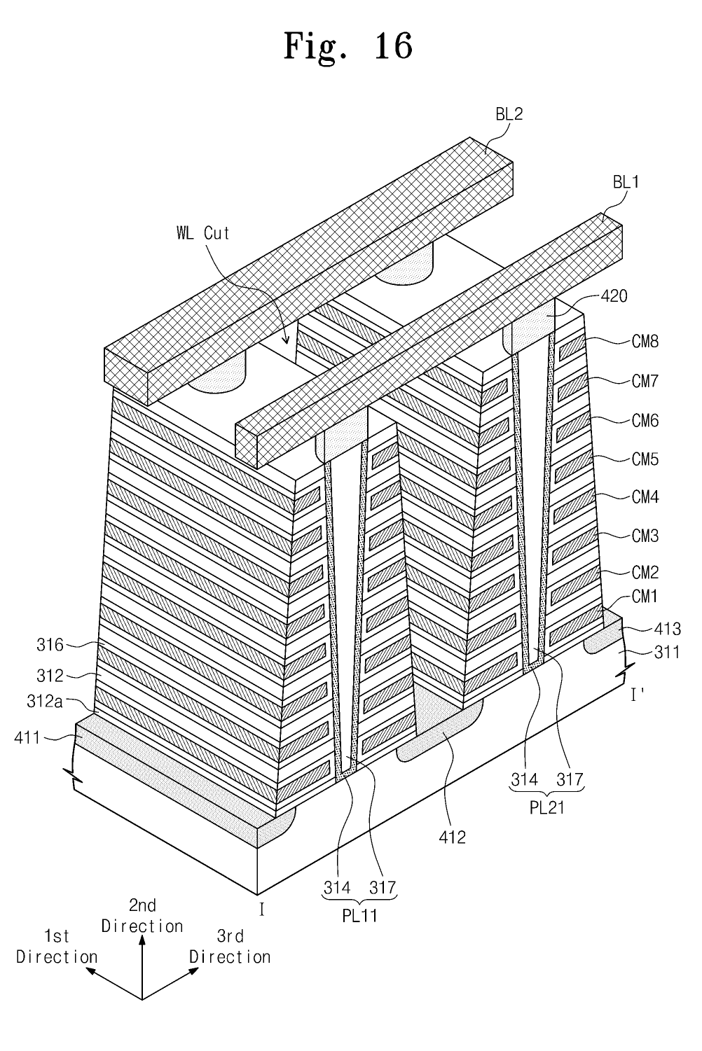

FIG. 15 is a top view of one of memory blocks in FIG. 14. FIG. 16 is a cross-sectional view taken along a line I-I′ in FIG. 15.

Referring to FIGS. 15 and 16, a memory block BLKa may include structures extending along first to third directions.

A substrate 311 may be provided. The substrate 311 may be a well having a first conductive type, for example. The substrate 311 may be a p-well in which the Group III element such as boron is injected. The substrate 311 may be a pocket p-well which is provided within an n-well. Below, it is assumed that the substrate 311 is a p-well (or, a pocket p-well). However, the substrate 311 is not limited to a p-type.

A plurality of doping regions 411 to 413 extending along a first direction may be provided in the substrate 311. The doping regions 411 to 413 may be spaced apart from one another along a third direction. The doping regions 411 to 413 illustrated in FIGS. 15 and 16 may be referred to as to a first doping region 411, a second doping region 412, and a third doping region 413, respectively.

The first to third doping regions 411 to 413 may have a second conductive type different from that of the substrate 311. The first to third doping regions 411 to 413 may be n-type. Below, it is assumed that the first to third doping regions 411 to 413 are the n-type. However, the first to third doping regions 411 to 413 are not limited to the n-type.

Between two adjacent doping regions of the first to third doping regions 411 to 413, a plurality of insulation materials 312 and 312a may be provided on the substrate 311 sequentially along a second direction (i.e., a direction perpendicular to the substrate 311). The insulation materials 312 and 312a may be spaced apart along the second direction. The insulation materials 312 and 312a may extend along the first direction. For example, the insulation materials 312 and 312a may include an insulation material such as a silicon oxide film. A thickness of the insulation material 312a contacting with the substrate 311 may be thinner than that of the insulation material 312.

Between two adjacent doping regions of the first to third doping regions 411 to 413, a plurality of pillars PL11, PL12, PL21, and PL22 may be arranged sequentially along the first direction so as to penetrate the plurality of insulation materials 312 and 312a along the second direction. In an embodiment, the pillars PL11, PL12, PL21, and PL22 may contact with the substrate 311 via the insulation materials 312.

In an embodiment, each of the pillars PL11, PL12, PL21, and PL22 may be formed of multiple layers. Each of the pillars PL11, PL12, PL21, and PL22 may include a channel film 314 and an inner material 317. In each of the pillars PL11, PL12, PL21, and PL22, a channel film may be formed to surround an inner material.

The channel films 314 may include a semiconductor material (e.g., silicon) having the first conductive type. For example, the channel films 314 may include a semiconductor material (e.g., silicon) having the same type as the substrate 311. Below, it is assumed that the channel films 314 include p-type silicon. However, the channel films 314 are not limited to the p-type silicon. For example, the channel films 314 can include intrinsic semiconductor being a nonconductor.

The inner materials 317 may include an insulation material. For example, the inner materials 317 may include an insulation material such as silicon oxide. Alternatively, the inner materials 317 may include air gap.

Between two adjacent doping regions of the first to third doping regions 411 to 413, information storage films 316 may be provided on exposed surfaces of the insulation materials 312 and 312a and the pillars PL11, PL12, PL21, and PL22. In an embodiment, a thickness of the information storage film 316 may be less than a distance between the insulation films 312 and 312a.

Between two adjacent doping regions of the first to third doping regions 411 to 413, conductive materials CM1 to CM8 may be provided on exposed surfaces of the information storage films 316. In detail, the conductive materials CM1 to CM8 extending along the first direction may be provided between an information storage film, provided on a lower surface of an upper one of the insulation materials 312 and 312a, and an information storage film provided on an upper surface of a lower one of the insulation materials 312 and 312a.

The conductive materials CM1 to CM8 and the insulation materials 312 and 312a on the doping regions 411 to 413 may be separated by a word line cut WL cut. The conductive materials CM1 to CM8 may include a metallic conductive material. The conductive materials CM1 to CM8 can include a nonmetallic conductive material such as polysilicon.

In example embodiments, an information storage film can be removed which is provided on an upper surface of an insulation material, placed at the uppermost layer, from among the insulation materials 312 and 312a. In an embodiment, an information storage film provided at one, opposite to the pillars PL11, PL12, PL21, and PL22, from among sides of the insulation materials 312 and 312a.

A plurality of drains 420 may be provided on the plurality of pillars PL11, PL12, PL21, and PL22, respectively. The drains 420 may include a semiconductor material (e.g., silicon) having the second conductive type, for example. The drains 420 may include an n-type semiconductor material (e.g., silicon). Below, it is assumed that the drains 420 include n-type silicon. However, the prevent invention is not limited thereto. In an embodiment, the drains 420 can be extended toward upper portions of the channel films 314 of the pillars PL11, PL12, PL21, and PL22.

Bit lines BL1 and BL2 extending in the third direction may be provided on the drains 420 so as to be spaced apart from one another along the first direction. The bit lines BL1 and BL2 may be coupled with the drains 420. In an embodiment, the drains 420 and the bit lines BL1 and BL2 may be connected via contact plugs (not shown). The bit lines BL1 and BL2 may include a metallic conductive material. Alternatively, the bit lines BL1 and BL2 may include a nonmetallic conductive material such as polysilicon.

Below, rows and columns of the pillars PL11, PL12, PL21, and PL22 of a memory block BLKa will be defined. Rows of the pillars PL11, PL12, PL21, and PL22 may be defined according to whether the conductive materials CM1 to CM8 are separated or not.

Pillars PL11 and PL12 coupled with the conductive materials CM1 to CM8 between the first doping region 411 and the second doping region 412 via the information storage films 116 may be defined as a first row of pillars. Pillars PL21 and PL22 coupled with the conductive materials CM1 to CM8 between the second doping region 412 and the third doping region 413 via the information storage films 116 may be defined as a second row of pillars.

Columns of pillars PL11, PL12, PL21, and PL22 may be defined according to the bit lines BL1 and BL2. Pillars PL11 and PL21 connected with the bit line BL1 via the drains 420 may be defined as a first column of pillars. Pillars PL12 and PL22 connected with the bit line BL2 via the drains 420 may be defined as a second column of pillars.

Below, heights of the conductive materials CM1 to CM8 may be defined. The conductive materials CM1 to CM8 may have first to eighth heights according to a distance from the substrate 311. The conductive material CM1 closest to the substrate 311 may have a first height, and the conductive material CM8 closest to the bit lines BL1 and BL2 may have an eighth height.

Each of the pillars PL11, PL12, PL21, and PL22 may constitute a cell string with an adjacent information storage film 116 and an adjacent conductive material CMj (j=1 to 8). That is, the pillars PL11, PL12, PL21, and PL22 may form cell strings with information storage films 316 and the conductive materials CM1 to CMB.

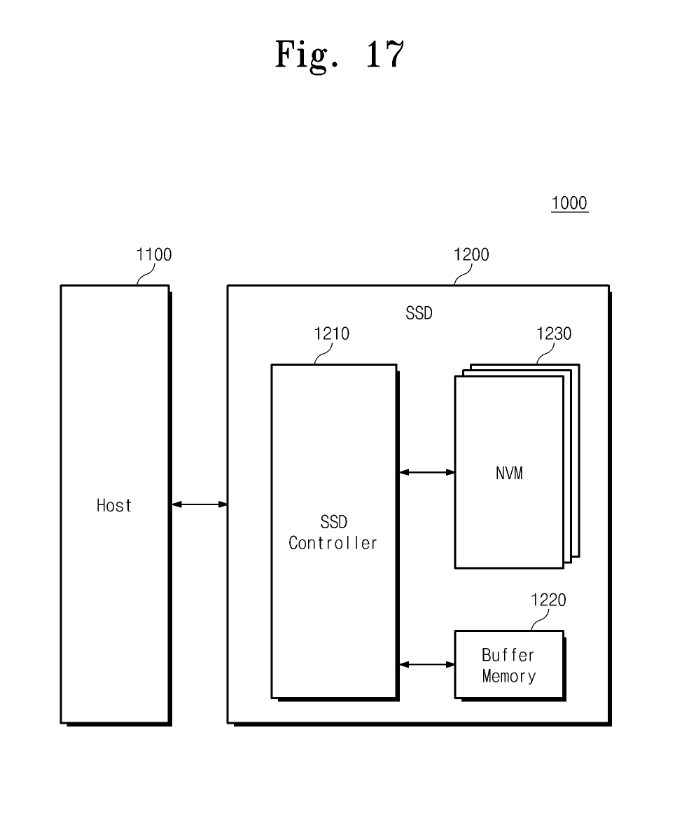

FIG. 17 is a block diagram illustrating a user device including a solid state disk according to at least one example embodiment. Referring to FIG. 17, a user device 1000 may include a host 1100 and an SSD 1200. The SSD 1200 may include an SSD controller 1210, a buffer memory 1220, and a nonvolatile memory device 1230. According to at least one example embodiment, the nonvolatile memory device 1230 may have the same structure and operation as that described above with reference to FIG. 3

The SSD controller 1210 may provide physical interconnection between the host 1100 and the SSD 1200. The SSD controller 1210 may provide an interface with the SSD 1200 corresponding to a bus format of the host 1100. In particular, the SSD controller 1210 may decode a command provided from the host 1100. The SSD controller 1210 may access the nonvolatile memory device 1230 according to the decoding result. The bus format of the host 1100 may include USB (Universal Serial Bus), SCSI (Small Computer System Interface), PCI express, ATA, PATA (Parallel ATA), SATA (Serial ATA), SAS (Serial Attached SCSI), and the like.

The buffer memory 1220 may temporarily store write data provided from the host 1100 or data read out from the nonvolatile memory device 1230. In the event that data existing in the nonvolatile memory device 1230 is cached at a read request of the host 1100, the buffer memory 1220 may support a cache function of providing cached data directly to the host 1100. Typically, a data transfer speed of a bus format (e.g., SATA or SAS) of the host 1100 may be higher than that of a memory channel of the SSD 1200. That is, in the event that an interface speed of the host 1100 is remarkably fast, lowering of the performance due to a speed difference may be minimized by providing the buffer memory 1220 having a large storage capacity.

The buffer memory 1220 may be formed of a synchronous DRAM to provide sufficient buffering to the SSD 1200 used as an auxiliary mass storage device. However, the buffer memory 1220 is not limited to this disclosure.

The nonvolatile memory device 1230 may be provided as a storage medium of the SSD 1200. For example, the nonvolatile memory device 1230 may be formed of a NAND flash memory device having a mass storage capacity. The nonvolatile memory device 1230 may be formed of a plurality of memory devices. In this case, memory devices may be connected with the SSD controller 1210 by a channel unit. The nonvolatile memory device 1230 is not limited to a NAND flash memory device. For example, a PRAM, an MRAM, a ReRAM, a FRAM, a NOR flash memory, etc. may be used as a storage medium of the SSD 1200. Further, one or more of the example embodiments discussed above may be applied to a memory system which uses different types of memory devices together.

The nonvolatile memory device 1230 may include an on-chip randomizer. Thus, the burden associated with randomization or de-randomization of the SSD controller 1210 may be reduced. Further, the nonvolatile memory device 1230 may satisfy both the reliability on data and efficiency of randomization using the on-chip randomizer according to at least one example embodiment.

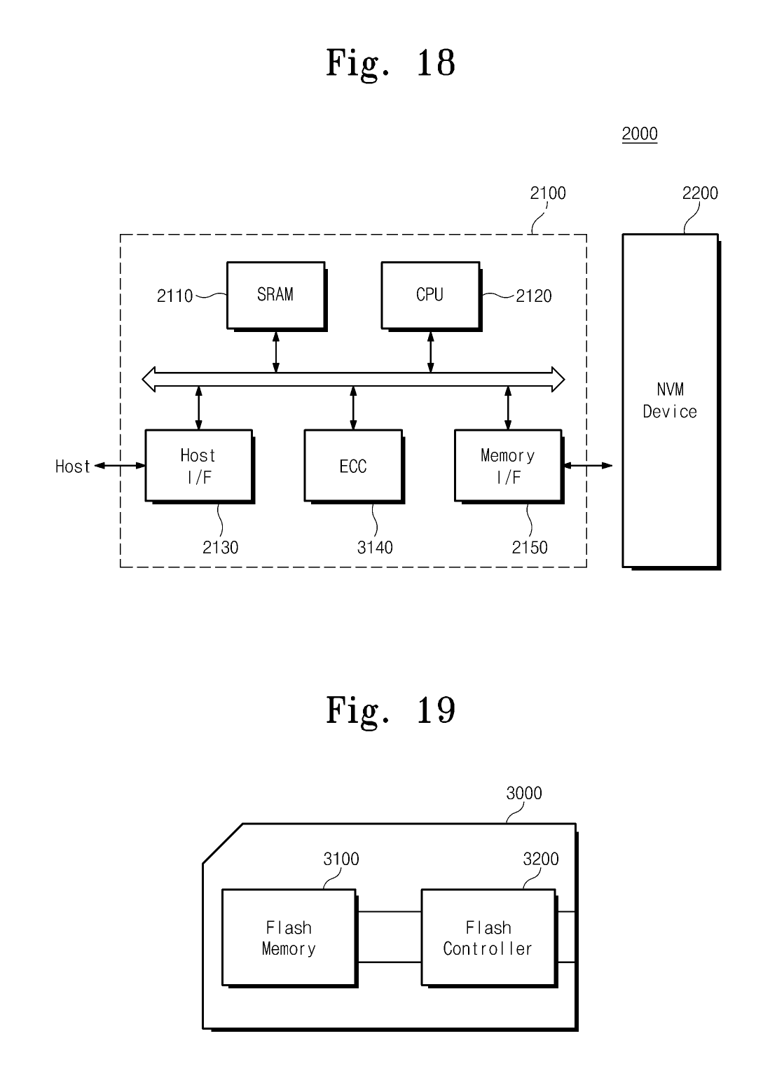

FIG. 18 is a block diagram illustrating a memory system according to at least one example embodiment. Referring to FIG. 18, a memory system 2000 may include a memory controller 2100 and a nonvolatile memory device 2200.

The nonvolatile memory device 2200, may have the same structure and operation as that described above with reference to FIG. 3, and description thereof is thus omitted.

The memory controller 2100 may be configured to control the nonvolatile memory device 2200. An SRAM 2130 may be used as a working memory. A host interface 2120 may include the data exchange protocol of a host connected with the memory system 2000. An ECC circuit 2240 may be configured to detect and correct an error of data read out from the nonvolatile memory device 2200. A memory interface 2160 may be configured to interface with the nonvolatile memory device 2200 according to at least one example embodiment. A CPU 2110 may be configured to perform an overall control operation for exchanging data. Although not shown, the memory system 2000 may further include a ROM which stores code data for interfacing with a host.

The memory controller 2100 may be configured to communicate with an external device (e.g., a host) via one of various interface protocols such as USB, MMC, PCI-E, SAS, SATA, PATA, SCSI, ESDI, IDE, etc.

The nonvolatile memory device 2200 may include an on-chip randomizer. Thus, the burden associated with randomization or de-randomization of the memory controller 2100 may be reduced. Further, the nonvolatile memory device 2200 may satisfy both the reliability on data and efficiency of randomization using the on-chip randomizer according to at least one example embodiment.

The memory system 2000 according to at least one example embodiment may be applied to one of various user devices such as computer, portable computer, Ultra Mobile PC (UMPC), workstation, net-book, PDA, web tablet, wireless phone, mobile phone, smart phone, e-book, PMP (portable multimedia player), digital camera, digital audio recorder/player, digital picture/video recorder/player, portable game machine, navigation system, black box, 3-dimensional television, a device capable of transmitting and receiving information at a wireless circumstance, one of various electronic devices constituting home network, one of various electronic devices constituting computer network, one of various electronic devices constituting telematics network, RFID, or one of various user devices constituting a home network.

FIG. 19 is a block diagram illustrating a data storage device according to still at least one example embodiment. Referring to FIG. 19, a data storage device 3000 may include a flash memory 3100 and a flash controller 3200. The flash controller 3200 may control the flash memory 3100 in response to control signals received from the outside of the data storage device 3000.

The flash memory 3100 may have the same structure and operation as that described above with reference to FIG. 3. The flash memory 3100 may be configured to have one of a stack flash structure having arrays stacked in multi-layer, a source-drain free flash structure, a pin-type flash structure, and a three-dimensional flash structure.

The data storage device 3000 may be a memory card device, an SSD device, a multimedia card device, an SD device, a memory stick device, a HDD device, a hybrid drive device, or a USB flash device. For example, the data storage device 3000 may be a card satisfying the industrial standard for using a user device such as a digital camera, a personal computer, etc.

The flash memory 3100 may include an on-chip randomizer. Thus, the burden associated with randomization or de-randomization of the flash controller 3200 may be reduced. Further, the flash memory 3100 may satisfy both the reliability on data and efficiency of randomization using the on-chip randomizer according to at least one example embodiment.

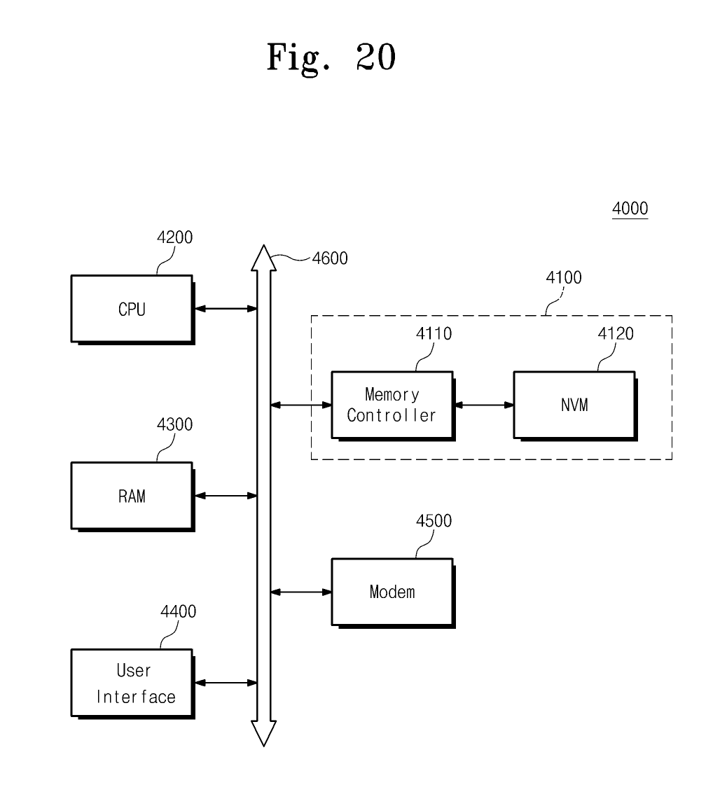

FIG. 20 is a block diagram schematically illustrating a computing system including a flash memory device according to at least one example embodiment. Referring to FIG. 20, a computing system 4000 may include a flash memory 4100, a memory controller 4200, a modem 4300 such as a baseband chipset, a microprocessor 4500, and a user interface 4600. The elements 4200, 4300, 4500, and 4600 may be electrically connected with a bus 4400.

The flash memory 4100 illustrated in FIG. 20 may have the same structure and operation as that described above with reference to FIG. 3. The flash memory 4100 may be configured to have one of a stack flash structure having arrays stacked in multi-layer, a source-drain free flash structure, a pin-type flash structure, and a three-dimensional flash structure.

In the event that the computing system 4000 is a mobile device, it may further comprise a battery 4700 for powering the computing system 4000. Although not shown, the computing system 4000 may further include an application chipset, a camera image processor (CIS), a mobile DRAM, and the like. The memory controller 4200 and the flash memory device 4100 may constitute a solid state drive (SSD) which uses a nonvolatile memory to store data, for example.

The flash memory 4100 may include an on-chip randomizer. Thus, the burden associated with randomization or de-randomization of the memory controller 4200 may be reduced. Further, the flash memory 4100 may satisfy both the reliability on data and efficiency of randomization using the on-chip randomizer according to at least one example embodiment.

In some embodiments, a nonvolatile memory device and/or a memory controller may be packed by various types of packages such as PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

With a nonvolatile memory device and an operating method according to at least one example embodiment, it is possible to randomization may be made efficiently within the nonvolatile memory device. Thus, it is possible to improve the performance of the nonvolatile memory device and the integrity of data stored in the nonvolatile memory device.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

1. A method of operating a nonvolatile memory device which includes a first memory area and a second memory area, a number of pages being stored in each word line of the first memory area being smaller than a number of pages being stored in each word line of the second memory area, and the first memory area being configured to buffer data to be written in the second memory area, the method comprising:
reading pages stored in the first memory area;
storing the pages read from the first memory area in a page buffer;
receiving an address; and
randomizing data of the pages stored in the page buffer based on the address.

2. The method of claim 1, wherein randomizing the data of the pages stored in the page buffer based on the address includes,
generating a seed from the address;
generating a random sequence based on the seed; and
randomizing the data of the pages using the random sequence.

3. The method of claim 2, wherein generating a seed from the address includes generating seeds respectively corresponding to the pages.

4. The method of claim 2, wherein the seed is generated based on a lookup table having a bit value assigned according to the address.

5. The method of claim 1, wherein the address corresponds to a page address of the nonvolatile memory device.

6. The method of claim 1, further comprising:
programming the pages of randomized data in a target area of the second memory area.

7. The method of claim 6, wherein programming the pages of randomized data in a target area of the second memory area includes simultaneously programming at least two pages from among the pages of randomized data.

8. The method of claim 1, further comprising:
de-randomizing data of the pages read from the first memory area.

9. The method of claim 8, wherein de-randomizing pages read from the first memory area includes,
generating at least a seed from an address of each of pages stored in the page buffer;
generating a random sequence corresponding to each of the pages based on the seed; and
de-randomizing the data of the pages read from the first memory area using the random sequence.

10. The method of claim 1, wherein a randomizing operation is executed during a period where the address is input and a state signal of the nonvolatile memory device indicates a busy state.

11. The method of claim 1, wherein a randomizing operation starts in response to an input of the address regardless of a logic value of a state signal of the nonvolatile memory device.

12-14. (canceled)

15. A method of operating a nonvolatile memory device, the method comprising:
reading first data from a first memory area of the memory device, the first memory area being configured to buffer data to be written in a second memory area of the memory device;
storing the first data in a page buffer of the memory device;
receiving an address indicating a location in the second memory area at which to store the first data;
generating randomized data by randomizing bits of the first data based on the received address; and
storing the randomized data in the second memory at the location indicated by the received address.

16. The method of claim 15, wherein the first memory area and second memory area are configured such that a number of bits per cell of data stored in the first memory area is smaller than a number of bits per cell of data stored in the second memory area.

17. The method of claim 16, wherein the first memory area includes single level cells (SLCs) and the second memory area includes multilevel cells (MLCs).

18. The method of claim 15, wherein generating the randomized data includes
generating a random sequence based on the address; and
randomizing the bits of the first data using the random sequence.

19. The method of claim 17, wherein randomizing the bits of the first data using the random sequence includes performing an exclusive-OR (XOR) operation on the bits of the first data using the random sequence.
